(19) United States
(12) Patent Application Publication
(10) Pub. No.: US 2009/0190303 A1
(43) Pub. Date: Jul. 30, 2009

(54) HEAT DISSIPATION PLATE, GAP ADJUSTING JIG FOR HEAT DISSIPATION AND MOTHERBOARD

(75) Inventors: Hung-Chun Chu, Taipei (TW); Chun-Teng Chiu, Taipei (TW); Zhi-Kai Chen, Taipei (TW); Chien-Han Kao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTeK COMPUTER INC., Taipei (TW)

(21) Appl. No.: 12/131,935

(22) Filed: Jun. 3, 2008

(30) Foreign Application Priority Data
Jun. 4, 2007 (TW) 96119913

(51) Int. Cl. G06F 1/20; H05K 7/20

(52) U.S. Cl. 361/679.47; 361/704; 361/679.54; 361/700

(57) ABSTRACT

A gap adjusting jig for heat dissipation is suitable to hold at least a heat source of a plate-shaped module. The gap adjusting jig for heat dissipation includes a first heat dissipation plate and a second heat dissipation plate and at least a gap adjusting element. A gap is formed between the first and second heat dissipation plates. The heat source is suitable to be provided in the gap and lean against the first and second heat dissipation plates. The gap adjusting element is connected between the first and second heat dissipation plates. The gap adjusting element is suitable to adjust the gap between the first and second heat dissipation plates to enable the first and second heat dissipation plates to hold the heat source.

### CROSS-REFERENCE TO RELATED APPLICATION

This application claims the priority benefit of Taiwan application serial no. 96119913, filed on Jun. 4, 2007. The entirety of the above-mentioned patent application is hereby incorporated by reference herein and made a part of specification.

### BACKGROUND OF THE INVENTION

1. Field of the Invention

The invention relates to a motherboard and, more particularly, to a jig for assisting a motherboard in dissipating heat.

2. Description of the Related Art

FIG. 1 is schematic diagram showing a conventional host. As shown in FIG. 1, a motherboard 110, a power supplying device 120, an optical drive 130, a floppy drive 140 and a host fan 150 are provided in a host 100. The motherboard 110 is located at one side of the host 100. The motherboard 110 is provided with a central processing unit (CPU), a plurality of inserted cards such as a graphics card, an audio card or a memory card and other electronic elements. The power supplying device 120 is located at the bottom of the host 100, and it is suitable to be connected to an external power source. The power supplying device 120 is electrically connected to the motherboard 110 via electric wire to allow the motherboard 110 to have sufficient electric power to operate.

The optical drive 130 and the floppy drive 140 are parallelly provided at the front of the host 100 and are electrically connected to the motherboard 110 via ribbon cables, respectively. The optical drive 130 and the floppy drive 140 are used to support an optical disk and a magnetic disk, respectively, to read data stored in the optical disk and the magnetic disk or store data to the optical disk and the magnetic disk.

The CPU, the graphics card, the audio card, the memory card or other electronic elements on the motherboard 110 generate heat when they operate. The power supplying device 120, the optical drive 130 and the floppy drive 140 also generate heat when they operate. When a great deal of heat gathers in the host 100, the operation of the motherboard 110, the power supplying device 120, the optical drive 130 and the floppy drive 140 is affected, and even the lifespan of the electronic devices is shortened.

Therefore, the host 100 needs to be provided with the host fan 150. The host fan 150 provided at the back of the host 100 is used to dissipate the heat in the host 100 out of the host 100 in a forced convection mode.

Although the host fan 150 can decrease the interior temperature of the host 100, the electronic elements continuously operate and generate heat, and then the temperature of the place around the heat sources is still high. Thus, the operation of the electronic elements is affected.

### BRIEF SUMMARY OF THE INVENTION

The invention provides a gap adjusting jig for heat dissipation to enhance the heat dissipation effect of a motherboard.

The invention provides a motherboard having a preferred heat dissipation effect.

The invention provides a heat dissipation plate capable of enhancing the heat dissipation effect of a plate-shaped module on a motherboard.

The invention provides a gap adjusting jig for heat dissipation, and the gap adjusting jig for heat dissipation is suitable to hold at least a heat source of a plate-shaped module. The gap adjusting jig for heat dissipation includes a first heat dissipation plate, a second heat dissipation plate and at least a gap adjusting element. A gap is formed between the first heat dissipation plate and the second heat dissipation plate, and the heat source is suitable to be located in the gap and lean against the first heat dissipation plate and the second heat dissipation plate. The gap adjusting element is connected between the first and second heat dissipation plates and is suitable to adjust the gap between the first and second heat dissipation plates to enable the first and second heat dissipation plates to hold the heat source.

In one embodiment of the invention, the plate-shaped module is a memory card, and the heat source is a memory chip.

In one embodiment of the invention, the memory card further includes a third heat dissipation plate leaning against the memory chip.

In one embodiment of the invention, the material of the first heat dissipation plate and the second heat dissipation plate includes metal.

In one embodiment of the invention, the second heat dissipation plate includes a body and a holding base. The body has a surface facing the first heat dissipation plate, and the holding base is provided at the surface and is suitable to contact the heat source.

In one embodiment of the invention, the body and the holding base are integrally formed.

In one embodiment of the invention, the gap adjusting jig for heat dissipation further includes a heat pipe, wherein part of the heat pipe is embedded in the holding base.

In one embodiment of the invention, the gap adjusting element includes a stud and a nut. The stud is connected to the first heat dissipation plate and the second heat dissipation plate, and the nut is connected to the stud.

In one embodiment of the invention, each of the first heat dissipation plate and the second heat dissipation plate further includes at least an opening, the openings are correspondingly provided, and the stud is correspondingly provided through the openings.

In one embodiment of the invention, the gap adjusting element includes a spring.

The invention further provides a motherboard including a base plate, a heat sink and a gap adjusting jig for heat dissipation. The base plate has at least a slot and at least a first heat source. The heat sink is provided on the base plate and is coupled to the first heat source. The gap adjusting jig for heat dissipation can be detachably provided on the slot, and it includes a first heat dissipation plate, a second heat dissipation plate and at least a gap adjusting element. A gap is formed between the first and second heat dissipation plates. The gap adjusting element is connected between the first and second heat dissipation plates and is suitable to adjust the gap between the first and second heat dissipation plates.

In one embodiment of the invention, the first heat source is a south bridge chip.

In one embodiment of the invention, the material of the first heat dissipation plate and the second heat dissipation plate includes metal.

In one embodiment of the invention, the heat sink is coupled to the first heat source via a first heat pipe.

In one embodiment of the invention, the motherboard further includes a heat conduction base provided on the base plate, wherein part of the first heat pipe is provided through the heat conduction base.

In one embodiment of the invention, the motherboard further includes a second heat pipe, wherein one end of the second heat pipe is connected to the gap adjusting jig for heat dissipation, and the other end of the second heat pipe is movably provided through the heat conduction base.

In one embodiment of the invention, the second heat dissipation plate includes a body and a holding base. The body has a surface facing the first heat dissipation plate, and the holding base is provided at the surface.

In one embodiment of the invention, the body and the holding base are integrally formed.

In one embodiment of the invention, the motherboard further includes a second heat pipe, wherein one end of the second heat pipe is coupled to the heat sink, and the other end of the second heat pipe is embedded in the holding base.

In one embodiment of the invention, the gap adjusting element includes a stud and a nut. The stud is connected to the first and second heat dissipation plates, and the nut is connected to the stud.

In one embodiment of the invention, each of the first heat dissipation plate and the second heat dissipation plate includes at least an opening, respectively, and the openings are correspondingly provided. The stud is correspondingly provided through the openings.

In one embodiment of the invention, the gap adjusting element includes a spring.

In one embodiment of the invention, the motherboard further includes a plate-shaped module provided in the slot. The plate-shaped module has a second heat source, and the gap adjusting jig for heat dissipation contacts the second heat source.

In one embodiment of the invention, the plate-shaped module is a memory card, and the second heat source is a memory chip.

In one embodiment of the invention, the memory card further includes a third heat dissipation plate leaning against the memory chip.

In one embodiment of the invention, the motherboard further includes a fan provided on the base plate, and the fan is located between the heat sink and the slot.

The invention further provides a heat dissipation plate, and the heat dissipation plate is suitable to contact at least a heat source of a plate-shaped module on a motherboard. The motherboard has a heat conduction base. The heat dissipation plate includes a body, a holding base and a heat pipe. The body has a surface facing the heat source. The holding base is provided at the surface and is suitable to contact the heat source. One end of the heat pipe is embedded in the holding base, and the other end of the heat pipe is suitable to be embedded in the heat conduction base.

In one embodiment of the invention, the plate-shaped module is a memory card, and the heat source is a memory chip.

In one embodiment of the invention, the memory card further includes a third heat dissipation plate leaning against the memory chip.

In one embodiment of the invention, the material of the heat dissipation plate includes metal.

In one embodiment of the invention, the body and the holding base are integrally formed.

Via the gap adjusting jig for heat dissipation or the heat dissipation plate of the invention, heat dissipation area of the heat source of the plate-shaped module increases to enhance the heat dissipation effect. The gap adjusting element can reliably allow the heat source to be held, and the heat dissipation plate can reliably contact the heat source. Therefore, the gap adjusting jig for heat dissipation or the heat dissipation plate can be applied to the heat source of the plate-shaped module on the motherboard to effectively enhance the heat dissipation effect.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1 is schematic diagram showing a conventional host.

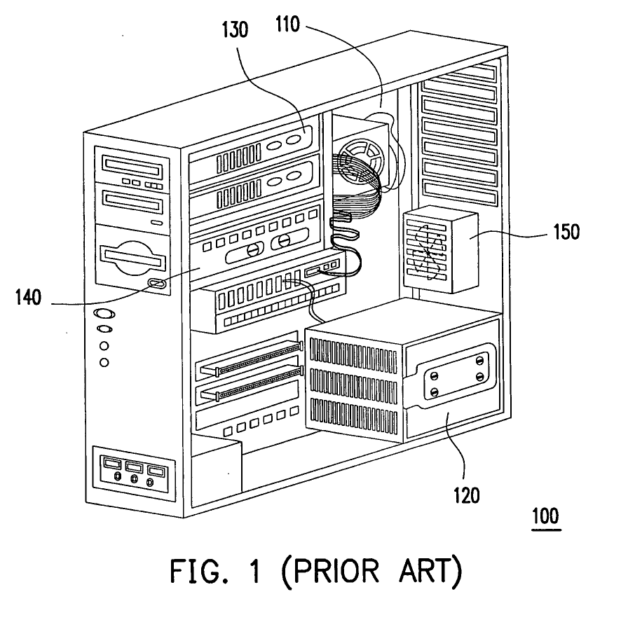

FIG. 2 is a schematic diagram showing a motherboard of the first embodiment of the invention.

FIG. 3 is a schematic diagram showing a gap adjusting jig for heat dissipation shown in FIG. 2.

FIG. 4 is a schematic diagram showing a memory card.

FIG. 5 is a schematic diagram showing a memory card provided with a third heat dissipation plate.

FIG. 6 is a schematic diagram showing a heat dissipation plate provided on a motherboard according to the second embodiment of the invention.

### DETAILED DESCRIPTION OF THE EMBODIMENTS

### First Embodiment

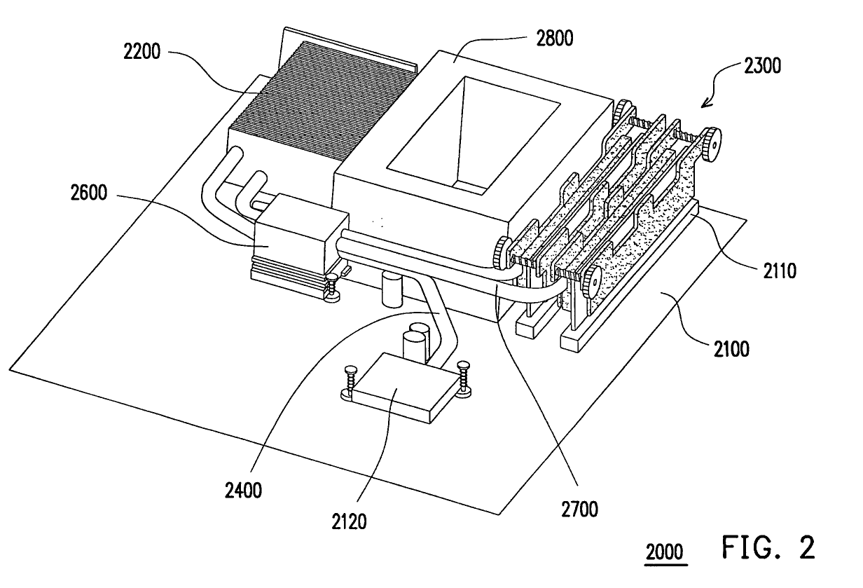

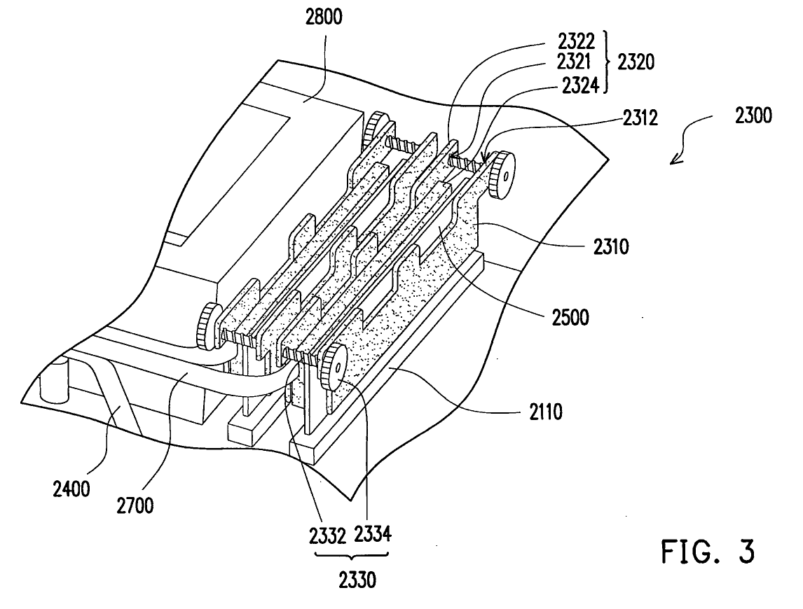

FIG. 2 is a schematic diagram showing a motherboard of the first embodiment of the invention, and FIG. 3 is a schematic diagram showing a gap adjusting jig for heat dissipation shown in FIG. 2. As shown in FIG. 2 and FIG. 3, a motherboard 2000 includes a base plate 2100, a heat sink 2200 and a gap adjusting jig for heat dissipation 2300.

The base plate 2100 has at least a slot 2110 and at least a first heat source. The first heat source is, for example, a south bridge chip 2120 which is in charge of controlling peripheral devices connected to a peripheral component interface (PCI) bus. The base plate 2100 has a north bridge chip (not shown), and the north bridge chip is in charge of processing signal transmission among a central processing unit (CPU) and a main memory and a PCI bus. The slot 2110 is suitable to hold a plate-shaped module, and the plate-shaped module may be a memory card, a graphics card or an audio card. The plate-shaped module at least has a second heat source.

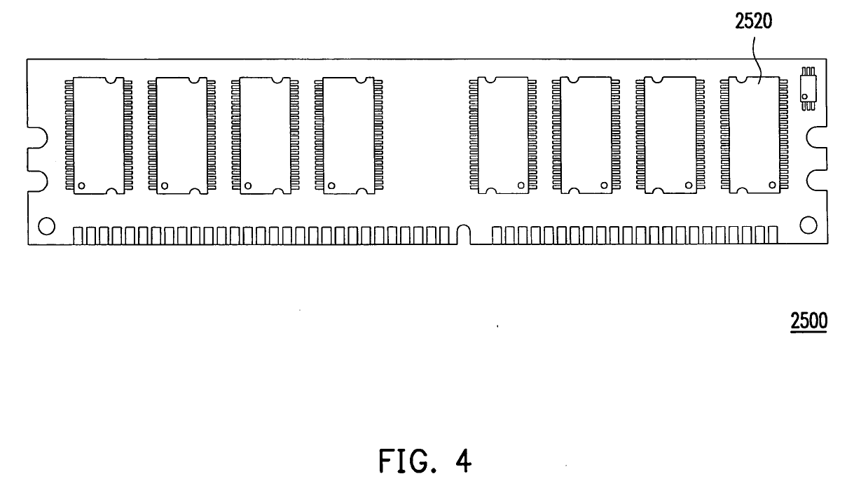

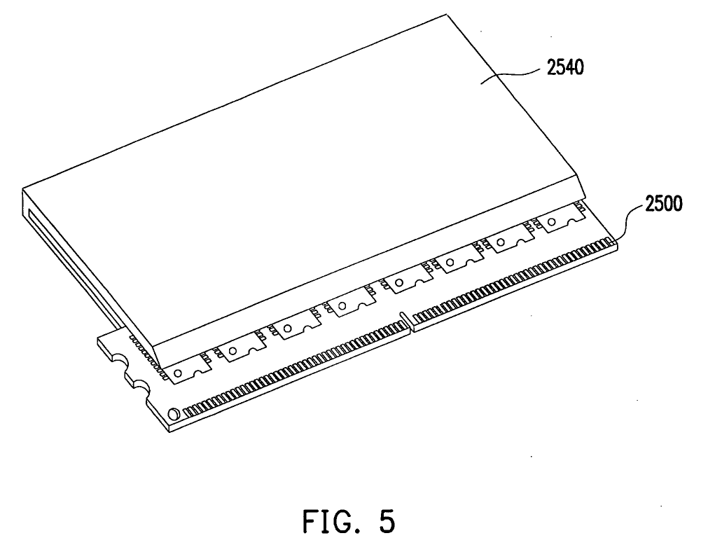

FIG. 4 is a schematic diagram showing a memory card. As shown in FIG. 4, the plate-shaped module is, for example, the memory card 2500. The heat source of the memory card 2500 is the memory chip 2520. When the memory chip 2520 operates, it generates heat. FIG. 5 is a schematic diagram showing a memory card provided with a third heat dissipation plate. To rapidly dissipate the heat generated by the operation of the memory chip 2520, a third heat dissipation plate 2540 may also be provided at the memory card 2500. The third heat dissipation plate 2540 leans against the memory chip 2520 to increase the heat dissipation area of the memory chip 2520 to accelerate heat dissipation for the memory chip 2520. The thickness of the memory card 2500 on the market is various according to the standard of each supplier. A user can buy the memory card according to his hobby.

As shown in FIG. 2, to rapidly dissipate heat for the north bridge chip (not shown), the heat sink 2200 is provided on the north bridge chip on the base plate 2100 and is coupled to the south bridge chip 2120. In the embodiment, the heat sink 2200 is coupled to the south bridge chip 2120 via a first heat pipe 2400. Via the heat sink 2200, the heat of the south bridge chip 2120 can be rapidly dissipated to maintain the operation of the south bridge chip 2120 and prolong the lifespan of the south bridge chip 2120. To hold the first heat pipe 2400 and to prevent the first heat pipe 2400 from contacting other electronic elements on the base plate 2100 further to affect the operation of the motherboard 2000, the motherboard 2000 further includes a heat conduction base 2600. The heat conduction base 2600 is provided on the base plate 2100 and is located between the south bridge chip 2120 and the heat sink 2200. The first heat pipe 2400 is provided through the heat conduction base 2600, and two ends of the first heat pipe 2400 are connected to the south bridge chip 2120 and the heat sink 2200, respectively.

As shown in FIG. 2 and FIG. 3, the gap adjusting jig for heat dissipation 2300 is detachably provided on the slot 2110 and is suitable to hold the memory card 2500 inserted into the slot 2110 to accelerate the heat dissipation for the memory card 2500. The gap adjusting jig for heat dissipation 2300 includes a first heat dissipation plate 2310, a second heat dissipation plate 2320 and at least a gap adjusting element 2330.

A gap is formed between the first heat dissipation plate 2310 and the second heat dissipation plate 2320. The memory card 2500 is located between the first heat dissipation plate 2310 and the second heat dissipation plate 2320, and the first heat dissipation plate 2310 and the second heat dissipation plate 2320 are suitable to contact the memory chip 2520 of the memory card 2500. Via the first heat dissipation plate 2310 and the second heat dissipation plate 2320, the heat dissipation area of the memory chip 2520 increases to rapidly dissipate the heat for the memory chip 2520. The material of the first heat dissipation plate 2310 and the second heat dissipation plate 2320 is a good heat conductor such as metal. Therefore, the heat dissipation of the memory card 2500 is accelerated to allow the memory card 2500 to maintain good operation.

The gap adjusting element 2330 is connected between the first heat dissipation plate 2310 and the second heat dissipation plate 2320, and it can adjust relative positions of the first heat dissipation plate 2310 and the second heat dissipation plate 2320 to adjust the size of the gap, and then the first heat dissipation plate 2310 and the second heat dissipation plate 2320 can reliably hold the memory card 2500. In the embodiment, the gap adjusting element 2330 includes a stud 2332 and a nut 2334. The stud 2332 is connected to the first heat dissipation plate 2310 and-the second heat dissipation plate 2320, and the nut 2334 is connected to the stud 2332. The first heat dissipation plate 2310 and the second heat dissipation plate 2320 have an opening 2312 and an opening 2321, respectively, and the openings 2312 and 2321 are corresponding to each other. The stud 2332 is provided through the corresponding openings 2312 and 2321. The user can adjust the size of the gap by adjusting. the position of the nut 2334 on the stud 2332.

To accelerate the heat dissipation for the memory card 2500, the motherboard 2000 further includes a second heat pipe 2700, and the second heat pipe 2700 is coupled between the heat sink 2200 and the gap adjusting jig for heat dissipation 2300. To hold the second heat pipe 2700, the second heat dissipation plate 2320 includes a body 2322 and a holding base 2324. The body 2322 has a surface facing the first heat dissipation plate 2310, and the holding base 2324 is provided at the surface. The body 2322 and the holding base 2324 are integrally formed. One of the second heat pipe 2700 is embedded in the holding base 2324, and the other end of the second heat pipe 2700 is movably provided in the heat conduction base 2600.

The motherboard 2000 further includes a heat dissipation base 2800 provided on the base plate 2100. The heat dissipation base 2800 is provided on the CPU (not shown) and is located beside the heat sink 2200. The heat dissipation base 2800 is used to rapidly dissipate the heat for the CPU. To further rapidly dissipate the heat for the CPU, the heat dissipation base 2800 usually is additionally provided with a fan.

As shown in FIG. 2, FIG. 3 and FIG. 4, when the memory card 2500 is inserted into the slot 2110, to increase the heat dissipation effect of the memory card 2500, the user can place the gap adjusting jig for heat dissipation 2300 on the slot 2110. Then, the user can screw the nut 2334 toward the central part of the stud 2332. At that moment, the first heat dissipation plate 2310 and the second heat dissipation plate 2320 hold the memory card 2500 and contact the memory chip 2520. Via the first heat dissipation plate 2310 and the second heat dissipation plate 2320, the heat dissipation area of the memory chip 2520 increases, and then the heat dissipation effect is preferred.

Via the second heat pipe 2700 connected to the second heat dissipation plate 2320 and the heat sink 2200, the second heat dissipation plate 2320 can further rapidly dissipate the heat to remove the heat of the memory chip 2520.

Thickness of each memory card 2500 bought by each user is not the same. The advantage of the gap adjusting jig for heat dissipation 2300 of the embodiment is that the user can adjust the degree of screwing the nut 2334 to the stud 2332 according to the thickness of the memory card 2500 of each supplier, and then the gap adjusting jig for heat dissipation 2300 can reliably hold the memory card 2500 to increase the heat conduction effect of the memory card 2500.

As shown in FIG. 4 and FIG. 5, the thickness of the memory card 2500 provided with the third heat dissipation plate 2540 is different from the thickness of the memory card 2500 without the third heat dissipation plate 2540. The gap between the first heat dissipation plate 2310 and the second heat dissipation plate 2320 can be adjusted via the gap adjusting element 2330, and then the gap adjusting jig for heat dissipation 2300 can reliably hold the memory card 2500. The heat of the memory chip 2520 of the memory card 2500 can be rapidly dissipated.

Although the gap adjusting element 2330 in FIG. 3 is the stud 2332 and the nut 2334, in other embodiments, the gap adjusting element 2330 may be a spring. The user can apply force to open the first heat dissipation plate 2310 and the second heat dissipation plate 2320 in two opposite directions and make the first heat dissipation plate 2310 and the second heat dissipation plate 2320 provided around the memory card 2500. After the user stops applying force, the resilience of the spring enables the first heat dissipation plate 2310 and the second heat dissipation plate 2320 to hold the memory card 2500.

The gap adjusting element 2330 can be used to change the relative positions of the first heat dissipation plate 2310 and the second heat dissipation plate 2320, and therefore, the second heat pipe 2700 provided through the heat conduction base 2600 moves in the heat conduction base 2600 along with the second heat dissipation plate 2320. The heat of the second heat pipe 2700 is conducted to the heat sink 2200 via the heat conduction base 2600.

When the memory chip 2520 generates heat, the heat is conducted to the first heat dissipation plate 2310 and the second heat dissipation plate 2320. Then, the heat conducted to the first heat dissipation plate 2310 is dissipated to the ambient cold environment. The heat conducted to the second heat dissipation plate 2320 can be conducted to the heat conduction base 2600 via the second heat pipe 2700 first, and then it is conducted to the heat sink 2200 via the first heat pipe 2400 and is dissipated. In this way, the gap adjusting jig for heat dissipation 2300 can be used to rapidly dissipate the heat for the memory chip 2520 of the memory card 2500.

### Second Embodiment

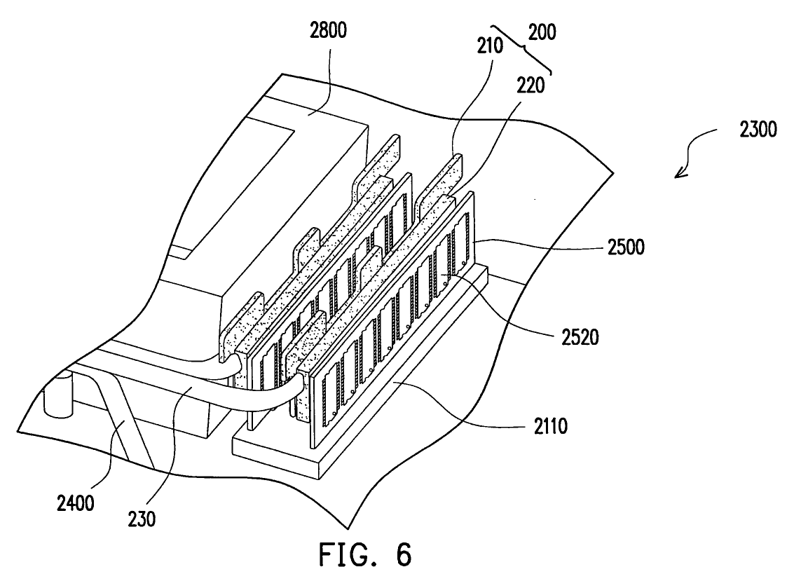

The embodiment is similar to the first embodiment, and the same or similar elements are denoted by the same or similar reference numbers. FIG. 6 is a schematic diagram showing a heat dissipation plate provided on a motherboard according to the second embodiment of the invention. As shown in FIG. 2 and FIG. 6, a heat dissipation plate 200 is provided on a memory card slot (not shown) to contact a memory chip 2520 of a memory card 2500 on a motherboard 2000 to dissipate the heat for the memory card 2500.

The heat dissipation plate 200 includes a body 210, a holding base 220 and a heat pipe 230. The body 210 has a surface facing the memory chip 2520. The holding base 220 is provided at the surface and is suitable to contact the memory chip 2520. The body 210 and the holding base 220 can be integrally formed, and the material of the body 210 and the holding base 220 is a good heat conductor such as metal. One end of the heat pipe 230 is embedded into the holding base 220, and the other end of the heat pipe 230 is moveably embedded into the heat conduction base 2600.

The difference between the embodiment and the first embodiment is that the heat dissipation plate 200 can structurally interfere with the memory card slot in a structural close assembly mode, a screwing mode, a fastening mode or a sliding rail mode. The heat dissipation plate 200 can also be directly provided on the memory card slot via the cooperation of shapes. Therefore, a user can conveniently move the heat dissipation plate 200 to allow the holding base 220 to correspondingly contact the memory chip 2520. The end of the heat pipe 230 is embedded into the heat conduction base 2600, and it can move with the heat dissipation plate 200, and then it moves in the heat conduction base 2600.

Similarly, via the heat dissipation plate 200, the heat of the memory card 2500 can be rapidly dissipated. In this way, the memory card 2500 can normally operate, and the lifespan of the memory card 2500 can be prolonged.

As shown in FIG. 5 and FIG. 6, if the memory card 2500 is provided with the third heat dissipation plate 2540, the user can conveniently move the heat dissipation plate 200 to allow the heat dissipation plate 200 to reliably contact the third heat dissipation plate 2540. In this way, the heat of the memory card 2500 can be rapidly dissipated. Therefore, the usage of the heat dissipation plate 200 is not limited by the thickness of the memory card 2500 and the third heat dissipation plate 2540.

To sum up, the heat dissipation area of the heat source of the plate-shaped module increases via the gap adjusting jig for heat dissipation holding the plate-shaped module on the motherboard or via the heat dissipation plate contacting the plate-shaped module on the motherboard, and then, the heat dissipation effect is enhanced. The heat dissipation efficiency of the plate-shaped module is preferred, and therefore, the motherboard can preferably operate, and the lifespan of the plate-shaped module and the motherboard can be prolonged.

The gap adjusting jig for heat dissipation can adjust the gap between the first and second heat dissipation plates according to the thickness of the plate-shaped module to enable the first and second heat dissipation plates reliably hold the plate-shaped module. The usage of the heat dissipation plates is not limited by the thickness of the plate-shaped module. Therefore, the user can determine to use the gap adjusting jig for heat dissipation or the heat dissipation plates or not by himself, which is elastic and convenient in use. The user can select the plate-shaped module by himself, and the selection of the plate-shaped module is elastic.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A gap adjusting jig for heat dissipation, which is suitable to hold at least a heat source of a plate-shaped module, the gap adjusting jig for heat dissipation comprising:
a first heat dissipation plate and a second heat dissipation plate, wherein a gap is formed between the first heat dissipation plate and the second heat dissipation plate, and the heat source is suitable to be located in the gap and lean against the first heat dissipation plate and the second heat dissipation plate; and
at least a gap adjusting element which is connected between the first heat dissipation plate and the second heat dissipation plate and is suitable to adjust the gap between the first heat dissipation plate and the second heat dissipation plate to enable the first heat dissipation plate and the second heat dissipation plate to hold the heat source.

2. The gap adjusting jig for heat dissipation according to claim 1, wherein the plate-shaped module is a memory card, and the heat source is a memory chip.

3. The gap adjusting jig for heat dissipation according to claim 2, wherein the memory card further comprises a third heat dissipation plate leaning against the memory chip.

4. The gap adjusting jig for heat dissipation according to claim 1, wherein the material of the first heat dissipation plate and the second heat dissipation plate comprises metal.

5. The gap adjusting jig for heat dissipation according to claim 1, wherein the second heat dissipation plate comprises:
a body having a surface facing the first heat dissipation plate; and
a holding base which is provided at the surface and is suitable to contact the heat source.

6. The gap adjusting jig for heat dissipation according to claim 5, wherein the body and the holding base are integrally formed.

7. The gap adjusting jig for heat dissipation according to claim 5 further comprising a heat pipe, wherein part of the heat pipe is embedded in the holding base.

8. The gap adjusting jig for heat dissipation according to claim 1, wherein the gap adjusting element comprises:
a stud connecting the first heat dissipation plate and the second heat dissipation plate; and
a nut connected to the stud.

9. The gap adjusting jig for heat dissipation according to claim 8, wherein each of the first heat dissipation plate and the second heat dissipation plate further comprises at least an opening, the openings are correspondingly provided, and the stud is correspondingly provided through the openings.

10. The gap adjusting jig for heat dissipation according to claim 1, wherein the gap adjusting element comprises a spring.

11. A motherboard comprising:
a base plate having at least a slot and at least a first heat source;
a heat sink provided on the base plate and coupled to the first heat source; and
a gap adjusting jig for heat dissipation detachably provided on the slot, the gap adjusting jig for heat dissipation comprising:
a first heat dissipation plate and a second heat dissipation plate, wherein a gap is formed between the first heat dissipation plate and the second heat dissipation plate; and
at least a gap adjusting element which is connected between the first heat dissipation plate and the second heat dissipation plate and is suitable to adjust the gap between the first heat dissipation plate and the second heat dissipation plate.

12. The motherboard according to claim 11, wherein the first heat source is a south bridge chip.

13. The motherboard according to claim 11, wherein the heat sink is coupled to the first heat source via a first heat pipe.

14. The motherboard according to claim 13, further comprising a heat conduction base provided on the base plate, wherein part of the first heat pipe is provided through the heat conduction base.

15. The motherboard according to claim 14, further comprising a second heat pipe, wherein one end of the second heat pipe is connected to the gap adjusting jig for heat dissipation, and the other end of the second heat pipe is movably provided through the heat conduction base.

16. The motherboard according to claim 11, wherein the second heat dissipation plate comprises:
a body having a surface facing the first heat dissipation plate; and
a holding base provided at the surface.

17. The motherboard according to claim 11, farther comprising a plate-shaped module provided at the slot, wherein the plate-shaped module has a second heat source, and the gap adjusting jig for heat dissipation contacts the second heat source wherein the plate-shaped module is a memory card, and the second heat source is a memory chip.

18. A heat dissipation plate which is suitable to contact at least a heat source of a plate-shaped module on a motherboard, wherein the motherboard has a heat conduction base, the heat dissipation plate comprising:
a body having a surface facing the heat source;
a holding base which is provided at the surface and is suitable to contact the heat source; and
a heat pipe, wherein one end of the heat pipe is embedded in the holding base, and the other end of the heat pipe is suitable to be embedded in the heat conduction base.

19. The heat dissipation plate according to claim 18, wherein the plate-shaped module is a memory card, and the heat source is a memory chip.

20. The heat dissipation plate according to claim 18, wherein the material of the heat dissipation plate comprises metal.
